(19) United States
(12) Patent Application Publication
(10) Pub. No.: US 2012/0140389 A1
(43) Pub. Date: Jun. 7, 2012

(54) Cover Unit and Display Device Having the Same

(75) Inventor: Jung-Ho Hwang, Yongin-City (KR)

(73) Assignee: SAMSUNG MOBILE DISPLAY CO., LTD., Yongin-City (KR)

(21) Appl. No.: 13/289,152

(22) Filed: Nov. 4, 2011

(30) Foreign Application Priority Data
Dec. 3, 2010 (KR) 10-2010-0122704

(51) Int. Cl. H05K 5/00

(52) U.S. Cl. 361/679.01

(57) ABSTRACT

A cover unit may include: a panel cover for wrapping and supporting at least a part of a display panel for displaying an image; a stand for supporting the panel cover; and an angle control plate provided between the panel cover and the stand, combined with the panel cover and the stand through surface contacting, and including a first surface facing the stand and a second surface facing the panel cover. At least one of the first surface and the second surface has a slant with respect to the other. A display unit may include a display unit including a display panel for displaying an image, a wire connected to the display panel, and a driver connected to the wire and driving the display panel, and a cover unit as described above.

### CLAIM OF PRIORITY

This application makes reference to, incorporates the same herein, and claims all benefits accruing under 35 U.S.C. §119 from an application earlier filed in the Korean Intellectual Property Office on the 3^{rd} of Dec. 2010 and there duly assigned Serial No. 10-2010-0122704.

### BACKGROUND OF THE INVENTION

1. Field of the Invention

The present invention relates generally to a cover unit. More particularly, the present invention relates to a cover unit for covering a display panel for displaying an image, and a display device including the same.

2. Description of the Related Art

A display device is an image displaying device including a display panel for displaying images.

A conventional display device includes a display panel, a display unit including a driver such as a printed circuit board (PCB) for driving the display panel, and a cover unit for covering the display unit.

Recently, a very thin display panel including organic light emitting diodes (OLED's) has been developed, and when a driver such as a flexible printed circuit (FPC) is positioned adjacent to the display panel, the thickness of the display device corresponding to a part where the display panel is positioned from among the whole part of the display device is increased by the thickness of the driver.

The above information disclosed in this Background section is only for enhancement of an understanding of the background of the described technology, and therefore it may contain information which does not form the prior art which is already known in this country to a person of ordinary skill in the art.

### SUMMARY OF THE INVENTION

The present invention has been developed in an effort to provide a thin display unit and a display device including the same, and therefore the invention relates to a cover unit for covering a display panel for displaying an image, and a display device including the same.

An exemplary embodiment of the present invention provides a cover unit which may include: a panel cover for wrapping and supporting at least a part of a display panel for displaying an image; a stand for supporting the panel cover; and an angle control plate provided between the panel cover and the stand, the angle control plate being combined with the panel cover and the stand through surface contacting, and including a first surface facing the stand and a second surface facing the panel cover; wherein at least one of the first surface and the second surface has a slant with respect to another of the first surface and the second surface.

The panel cover which may include: a front cover facing a front of the display panel; and a rear cover facing a rear of the display panel and combined with the front cover, the rear cover including a first penetrating unit through which a wire connected to the display panel is passed; wherein a surface of the rear cover contacts the second surface of the angle control plate.

The angle control plate may include a second penetrating unit through which the wire is passed to the first penetrating unit.

The stand may include: a base to be set on a surface and having a driver for driving the display panel disposed therein; and a neck extending in an upward direction from the base, the neck including a third penetrating unit through which the wire from the first penetrating unit and the second penetrating unit passes, the neck also including a wire receiver for receiving the wire from the third penetrating unit; wherein a surface of the neck contacts the first surface of the angle control plate.

The panel cover, the angle control plate, and the stand are combined with screws.

Another embodiment of the present invention provides a display device which may include: a display unit including a display panel for displaying an image, a wire connected to the display panel, and a driver connected to the wire and driving the display panel; and a cover unit including a panel cover for wrapping and supporting at least a part of the display panel, the wire passing through the panel cover, a stand for supporting the panel cover and receiving the wire and the driver, and an angle control plate provided between the panel cover and the stand and combined with the panel cover and the stand through surface contacting, the angle control plate including a first surface facing the stand and a second surface facing the panel cover; wherein at least one of the first surface and the second surface has a slant.

The display panel may include an organic light emitting diode.

According to the embodiments of the present invention, a thin cover unit and a display device including the same are provided.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIGS. 1A and 1B show a display device according to an exemplary embodiment of the present invention.

FIG. 2 is an exploded perspective view of a display device according to an exemplary embodiment of the present invention.

FIG. 3 and FIG. 4 show a part in which an angle control plate is positioned in a display device according to an exemplary embodiment of the present invention.

FIGS. 5A and 5B show an angle control plate of FIG. 4.

### DETAILED DESCRIPTION OF THE INVENTION

The present invention will be described more fully hereinafter with reference to the accompanying drawings, in which exemplary embodiments of the invention are shown. As those skilled in the art will realize, the described embodiments may be modified in various different ways, all without departing from the spirit or scope of the present invention.

Accordingly, the drawings and description are to be regarded as illustrative in nature and not restrictive, and like reference numerals designate like elements throughout the specification.

The size and thickness of each component shown in the drawings are arbitrarily shown for understanding and ease of description, but the present invention is not limited thereto.

In addition, unless explicitly described to the contrary, the word “comprise” and variations such as “comprises” or “comprising” will be understood to imply the inclusion of stated elements but not the exclusion of any other elements. In addition, throughout the specification, the term “on” indicates that an element is either positioned on or below another element or positioned on the upper side of another element based on a gravity direction.

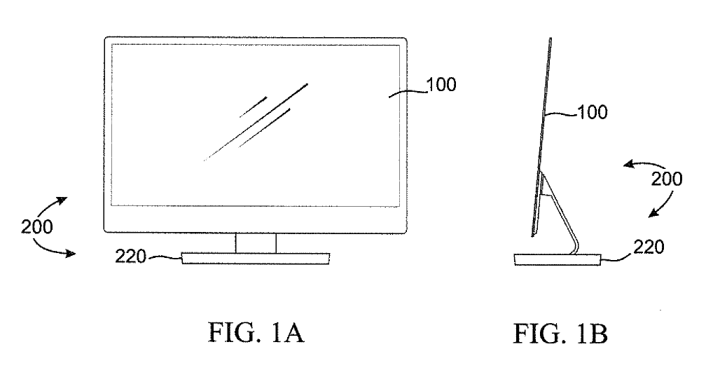

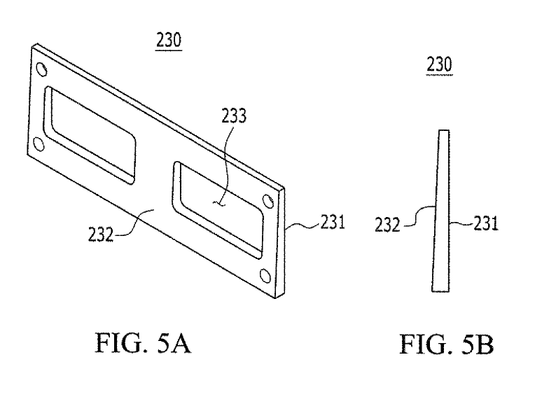

A display device according to an exemplary embodiment of the present invention will be described with reference to FIG. 1A thru FIG. 5.

FIGS. 1A and 1B show display device according to an exemplary embodiment of the present invention.

More specifically, FIG. 1A is a front view of a display part of the display device, and FIG. 1B is a side view of the display device.

As shown in FIGS. 1A and 1B, the display device includes a display unit 100 and a stand 220 of a cover unit 200. The display unit 100 displays an image, and the cover unit 200 covers the display unit 100 and includes the stand 220 for supporting the display unit 100.

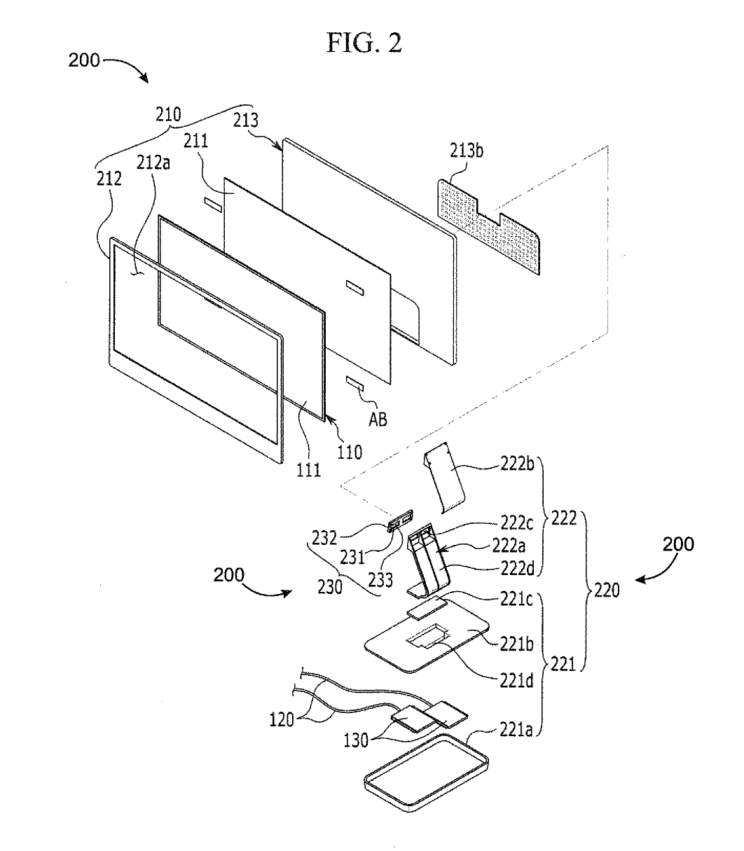

FIG. 2 is an exploded perspective view of a display device according to an exemplary embodiment of the present invention.

As shown in FIG. 2, the display unit 100 includes a display panel 110, a wire 120, and a driver 130.

The display panel 110 displays the image, and includes two substrates and an organic light emitting diode provided between the substrates. In this instance, the organic light emitting diode is a self light emitting element so that the display device needs no backlight unit for irradiating light to the display panel 110. That is, the display device can realize a very thin part where the display panel 110 is provided. At least a part of the display panel 110 is wrapped by a panel cover 210 of the cover unit 200 to be described, and is supported by the stand 220 of the cover unit 200.

The wire 120 connects the display panel 110 and the driver 130, and transmits a signal generated by the driver 130 to the display panel 110. The wire 120 connects the display panel 110 and the driver 130 through the panel cover 210, an angle control plate 230, and the stand 220 of the cover unit 200 to be described.

The driver 130 includes a printed circuit board (PCB), and generates a signal for displaying the image. The driver 130 is installed in the stand 220 of the cover unit 200.

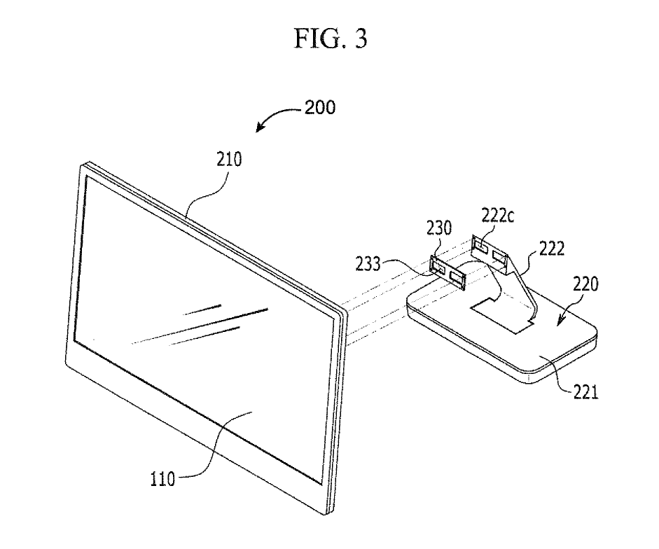

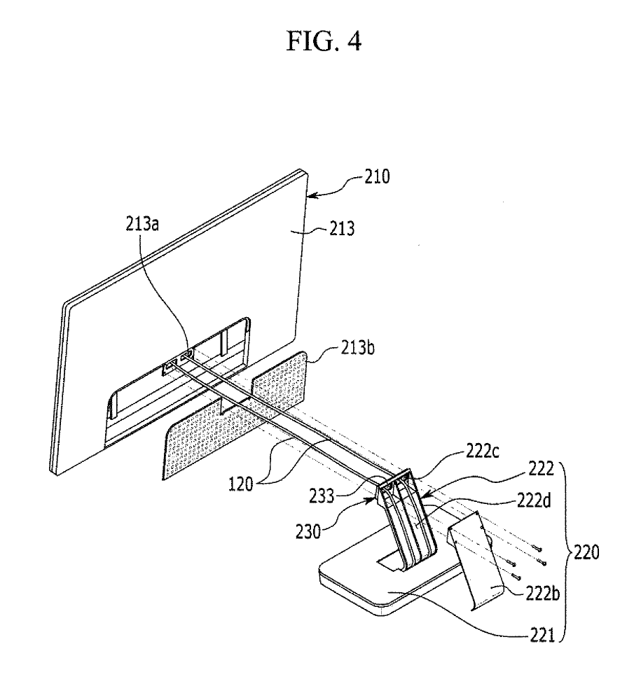

FIG. 3 and FIG. 4 show apart in which an angle control plate is positioned in a display device according to an exemplary embodiment of the present invention.

As shown in FIG. 2 thru FIG. 4, the cover unit 200 covers the display unit 100, and includes the panel cover 210, the stand 220, and the angle control plate 230.

The panel cover 210 wraps and supports at least a part of the display panel 110 so as to expose a display surface 111 of the display panel 110 for displaying the image, and includes a panel supporter 211, a front cover 212, and a rear cover 213.

The panel supporter 211 is adhered to a rear part of the display panel 110 by an adhesive member (AB), such as an adhesive tape, and supports the display panel 110. The display panel 110 supported by the panel supporter 211 is wrapped by the front cover 212 and the rear cover 213.

The front cover 212 includes an exposing hole 212a for exposing the display surface 111 of the display panel 110, and faces the front of the display panel 110. The front cover 212 is combined with the rear cover 213 along edges of the panel supporter 211 with the display panel 110 and the panel supporter 211 therebetween.

The rear cover 213 faces the rear of the display panel 110 supported by the panel supporter 211, and is combined with the front cover 212 along the edges of the panel supporter 211 with the display panel 110 and the panel supporter 211 therebetween. The rear cover 213 includes a first penetrating unit 213a (FIG. 4) through which the wire 120 passes, connected to the display panel 110, and a cover terminal 213b attachable by the rear cover 213.

The wire 120 connected to the display panel 110 through the first penetrating unit 213a of the rear cover 213 is extended outside the rear cover 213, and the wire 120 passing through the first penetrating unit 213a is connected to the driver 130 through a second penetrating unit 233 formed on the angle control plate 230 and a third penetrating unit 222c of a neck 222.

The rear cover 213 (FIG. 2) surface-contacts a second surface 232 of the angle control plate 230 and is slanted along a predetermined angle taken by the second surface 232 of the angle control plate 230, and the display panel 110 wrapped by the rear cover 213 is also slanted with a predetermined angle since the rear cover 213 is slanted.

The stand 220 (FIG. 4) is combined with the rear cover 213 so as to support the panel cover 210, and includes a base 221 and the neck 222.

The base 221 (FIG. 2) is to be set on a surface such as a desk, and receives the driver 130 for driving the display panel 110. The base 221 includes a bottom base 221a, a top base 221b, and a base cover 221c.

The bottom base 221a forms a predetermined space in which the driver 130 is received. The top base 221b is combined with the bottom base 221a to cover a top part of the bottom base 221a in which the driver 130 is received, and includes a base penetration hole 221d through which the wire 120 connected to the driver 130 passes. The base cover 221c, adjacent to the base penetration hole 221d, is combined with the top base 221b, and the neck 222 is provided on the base cover 221c.

The neck 222 extends in an upward direction from the base 221, and is combined with the rear cover 213 so as to support the panel cover 210 (see FIGS. 2 and 4). The neck 222 includes a neck main body 222a and a neck cover 222b.

The neck main body 222a extends in an upward direction from the base 221, and includes the third penetrating unit 222c through which the wire 120 in communication with the first penetrating unit 213a of the rear cover 213 passes, and the second penetrating unit 233 of the angle control plate 230 and a wire receiver 222d for receiving the wire 120 passing through the third penetrating unit 222c and then extending to the driver 130. The wire receiver 222d communicates with the base penetration hole 221d formed on the top base 221b, and the wire 120 passing through the wire receiver 222d is connected to the driver 130 received in the base 221 through the base penetration hole 221d. The neck main body 222a and the neck cover 222b are combined so as to cover the wire 120 passing through the wire receiver 222d corresponding to the wire receiver 222d.

The neck 222 surface-contacts a first surface 231 of the angle control plate 230, and the rear cover 213 surface-contacts the second surface 232 of the angle control plate 230 while the neck 222 surface-contacts the first surface 231 of the angle control plate 230 so that the rear cover 213 is slanted toward the neck 222 and is thus supported by the neck 222.

FIGS. 5A and 5B show an angle control plate of FIG. 4. More specifically, FIG. 5A is a perspective view of the angle control plate, and FIG. 5B is a side view of the angle control plate.

As shown in FIGS. 3, 4, 5A and 5B, the angle control plate 230 is provided between the panel cover 210 and the stand 220, and is combined with the panel cover 210 and the stand 220 through surface contacting between the panel cover 210 and the stand 220. In detail, the angle control plate 230 includes first surface 231 facing the neck main body 222a of the stand 220, and second surface 232 facing the rear cover 213 of the panel cover 210 and having a slant with respect to the first surface 231. The first surface 231 and the second surface 232 of the angle control plate 230 surface-contact the neck main body 222a and the rear cover 213. In this regard, the fact that the second surface 232 has a slant with respect to the first surface 231 signifies that at least one of the first surface 231 and the second surface 232 has a slant with respect to the other.

Furthermore, the angle control plate 230 includes the second penetrating unit 233 which communicates with the first penetrating unit 213a of the rear cover 213 and the third penetrating unit 222c of the neck main body 222a, and the wire 120 which connects the display panel 110 and the driver 130 passes through the second penetrating unit 233.

The above-described angle control plate 230, panel cover 210, and stand 220 can be combined with screws, and can be systematically combined with each other since they have a structure of systematic combination.

Accordingly, the panel cover 210 is combined with the stand 220 with the angle control plate 230 provided therebetween, and the panel cover 210 and the stand 220 surface-contact the first surface 231 and the second surface 232, respectively, of the angle control plate 230 so the panel cover 210 is slanted with a predetermined angle, and is thus supported by the stand 220. In addition, the wire 120 connected to the display panel 110, covered by the panel cover 210, is connected to the driver 130 received in the base 221 through the first penetrating unit 213a of the panel cover 210, the second penetrating unit 233 of the angle control plate 230, the third penetrating unit 222c and the wire receiver 222d of the neck 222, and the base penetration hole 221d of the base 221, and thus connects the display panel 110 to the driver 130.

Accordingly, since the display panel 110 including the organic light emitting diode which is a self light emitting element is wrapped by the panel cover 210, and since the driver 130 for driving the display panel 110 is received by the stand 220 for supporting the panel cover 210, the organic light emitting diode included in the display panel 110 is prevented from being deteriorated by heat which may occur when the driver 130 is driven. That is, the display panel 110 and the driver 130 included in the display unit 100 are separated from each other within the cover unit 200 so that a life-span-improved display device is provided.

Also, the thin display panel 110 including the organic light emitting diode, a self light emitting element, is wrapped by the panel cover 210, and the driver 130 for driving the display panel 110 is received in the stand 220, so that a thinner display device (in contrast to a conventional display device with a display panel and a driver which are covered and received adjacent to each other) may be provided.

Furthermore, since the angle of the panel cover 210 is controlled by the angle control plate 230 with respect to the stand 220 and the angle of the display surface 111 of the display panel 110 wrapped by the panel cover 210 is controlled, when the display device is set on a surface such as a desk, the display surface 111 of the display panel 110 can be set with an easily viewable angle by the user.

In addition, since the angle of the display surface 111 of the display panel 110 is controlled by controlling the angle of the panel cover 210 wrapping the display panel 110 with respect to the stand 220 by the angle control plate 230, production cost and time can be reduced in contrast to the conventional display device for controlling the angle of the display surface of the display panel by using an angle control member such as a hinge. That is, a display device including the cover unit 200 with reduced production cost and time is provided.

Also, since the angle of the display surface 111 of the display panel 110 relative to the stand 220 is controlled by the angle control plate 230, a display device with a thinner angle control part, in contrast to the conventional display device for controlling the angle of the display surface of the display panel by the angle control member such as a hinge is provided. That is, a thin display device is provided.

Furthermore, the display device can include an angle control plate 230 of various sizes having the second surface 232 with a slant having various angles compared to the first surface 231 according to the size of the display panel 110, the size of the panel cover 210 following the size of the display panel 110, and the size of the stand 220. This signifies that angle control plates 230 having various sizes and angles are applicable in correspondence to the display panels 110 with various sizes, thereby providing the display device with improved general purposes.

While this disclosure has been described in connection with what is presently considered to be practical exemplary embodiments, it is to be understood that the invention is not limited to the disclosed embodiments but, on the contrary, is intended to cover various modifications and equivalent arrangements included within the spirit and scope of the appended claims.

What is claimed is:

1. A cover unit, comprising:
a panel cover for wrapping and supporting at least a part of a display panel for displaying an image;
a stand for supporting the panel cover; and
an angle control plate provided between the panel cover and the stand, said angle control plate being combined with the panel cover and the stand through surface contacting, and including a first surface facing the stand and a second surface facing the panel cover, wherein at least one of the first surface and the second surface has a slant with respect to another of the first surface and the second surface.

2. The cover unit of claim 1, wherein the panel cover includes:
a front cover facing a front of the display panel; and
a rear cover facing a rear of the display panel and combined with the front cover, said rear cover including a first penetrating unit through which a wire connected to the display panel is passed;
wherein a surface of the rear cover contacts the second surface of the angle control plate.

3. The cover unit of claim 2, wherein the angle control plate includes a second penetrating unit through which the wire is passed to the first penetrating unit.

4. The cover unit of claim 3, wherein the stand includes:
a base to be set on a surface and having a driver for driving the display panel disposed therein; and
a neck extending in an upward direction from the base, said neck including a third penetrating unit through which the wire from the first penetrating unit and the second penetrating unit passes, said neck also including a wire receiver for receiving the wire from the third penetrating unit;
wherein a surface of the neck contacts the first surface of the angle control plate.

5. The cover unit of claim 1, wherein the panel cover, the angle control plate, and the stand are combined with screws.

6. A display device, comprising:
a display unit including a display panel for displaying an image, a wire connected to the display panel, and a driver connected to the wire and driving the display panel; and
a cover unit including a panel cover for wrapping and supporting at least a part of the display panel, the wire passing through the panel cover, a stand for supporting the panel cover and receiving the wire and the driver, and an angle control plate provided between the panel cover and the stand and combined with the panel cover and the stand through surface contacting, said angle control plate including a first surface facing the stand and a second surface facing the panel cover, wherein at least one of the first surface and the second surface has a slant.

7. The display device of claim 6, wherein the display panel includes an organic light emitting diode.

8. The display device of claim 6, wherein the panel cover includes:
a front cover facing a front of the display panel; and
a rear cover facing a rear of the display panel and combined with the front cover, said rear cover including a first penetrating unit through which the wire connected to the display panel is passed;
wherein a surface of the rear cover contacts the second surface of the angle control plate.

9. The display device of claim 8, wherein the angle control plate includes a second penetrating unit through which the wire is passed to the first penetrating unit.

10. The display device of claim 9, wherein the stand includes:
a base to be set on a surface and having the driver for driving the display panel disposed therein; and
a neck extending in an upward direction from the base, said neck including a third penetrating unit through which the wire from the first penetrating unit and the second penetrating unit passes, said neck also including a wire receiver for receiving the wire from the third penetrating unit;
wherein a surface of the neck contacts the first surface of the angle control plate.

11. The display device of claim 6, wherein the panel cover, the angle control plate, and the stand are combined with screws.
